(19) United States
(12) Patent Application Publication
(10) Pub. No.: US 2015/0090587 A1
(43) Pub. Date: Apr. 2, 2015

(54) ROTATABLE SPUTTER TARGET

(71) Applicants: Harald Gartner, Schöneck (DE); Thomas Berger, Norheim (DE)

(72) Inventors: Harald Gartner, Schöneck (DE); Thomas Berger, Norheim (DE)

(73) Assignee: APPLIED MATERIALS, INC., Santa Clara, CA (US)

(21) Appl. No.: 14/359,014

(22) PCT Filed: Dec. 9, 2011
(86) PCT No.: PCT/EP2011/072372

§ 371 Date: Jul. 31, 2014

(51) Int. Cl. H01J 37/34; F16B 35/00

(52) U.S. Cl. CPC H01J 37/3417; F16B 35/00
USPC 204/298.13; 204/298.12; 29/525.01; 29/525.11

(57) ABSTRACT

A target arrangement for providing material to be deposited on a substrate is provided. The target arrangement includes a target part (210) made of the material to be deposited. The target part may substantially have the shape of a hollow cylinder having an inner (260) and an outer (250) diameter, wherein the hollow cylinder includes a cylindrical surface (211) and two face surfaces (212). The target arrangement may further include a connection arrangement comprising a recess (230) within at least one of the face surfaces of target part. Also, a deposition apparatus including the target arrangement and a method for mounting a target arrangement in a deposition chamber are described.

### TECHNICAL FIELD OF THE INVENTION

Embodiments of the present invention relate to a target arrangement for a deposition apparatus and a method of mounting a target arrangement. Embodiments of the present invention particularly relate to target arrangement for a sputter deposition apparatus and a method of mounting a target arrangement in a sputter deposition apparatus.

### BACKGROUND OF THE INVENTION

Coated materials may be used in several applications and in several technical fields. For instance, substrates for displays are often coated by a physical vapor deposition (PVD) process.

Several methods are known for coating a substrate. For instance, substrates may be coated by a PVD process, a chemical vapor deposition (CVD) process, or a plasma enhanced chemical vapor deposition (PECVD) process etc. Typically, the process is performed in a process apparatus or process chamber, where the substrate to be coated is located. A deposition material is provided in the apparatus. In the case that a PVD process is used, the deposition material is present in the solid phase in a target. By bombarding the target with energetic particles, atoms of the target material, i.e. the material to be deposited, are ejected from the target. The atoms of the target material are deposited on the substrate to be coated.

In a PVD process, the sputter material, i.e. the material to be deposited on the substrate, may be arranged in different ways. For instance, the target may be made from the material to be deposited or may have a backing element on which the material to be deposited is fixed. The target including the material to be deposited is supported or fixed in a predefined position in a deposition chamber. In the case where a rotatable target is used, the target is connected to a rotating shaft or a connecting element connecting the shaft and the target.

However, using a backing element for the target increases manufacturing as well as recycling costs of the target. Using targets being made from the material to be deposited without a backing element allow for lower manufacturing and recycling costs, but face the problem of fixing the target in the chamber or connecting the target to a rotating shaft due to the characteristics of the material to be deposited. For instance, the material to be deposited may be too flexible or too porous for reliably fixing the target without additional components.

In view of the above, it is an object of the present invention to provide a target arrangement and a method for mounting a target arrangement, which overcomes at least some of the problems in the art.

### SUMMARY OF THE INVENTION

In light of the above, a cathode assembly for a target arrangement according to independent claim 1, a sputter deposition apparatus according to claim 10, and a method for mounting a target arrangement in a deposition apparatus according to independent claim 11 are provided. Further aspects, advantages, and features of the present invention are apparent from the dependent claims, the description, and the accompanying drawings.

According to a first embodiment of the present invention, a target arrangement for providing material to be deposited on a substrate is described. The target arrangement may include a target part made of the material to be deposited, wherein the target part has substantially the shape of a hollow cylinder having an inner diameter and an outer diameter. Further, the hollow cylinder of the target part may include a cylindrical surface and two face surfaces. The target arrangement may also include a connection arrangement including a recess within at least one of the face surfaces of the target part.

According to a second embodiment of the present invention, a target arrangement for providing material to be deposited on a substrate is described. The target arrangement may include a target part made of the material to be deposited, wherein the target part may have the shape of a tube having an inner diameter and an outer diameter. Further, the hollow cylinder of the target part may include a cylindrical surface and two face surfaces. The target arrangement may also include a connection arrangement including a recess within at least one of the face surfaces of the target part.

According to a further embodiment of the present invention, a sputter deposition apparatus is described including a target arrangement for providing material to be deposited on a substrate is described. The target arrangement may include a target part made of the material to be deposited, wherein the target part has substantially the shape of a hollow cylinder or a tube having an inner diameter and an outer diameter. Further, the hollow cylinder of the target part may include a cylindrical surface and two face surfaces. The target arrangement may also include a connection arrangement including a recess within at least one of the face surfaces of the target part.

According to a further embodiment of the present invention, a method of mounting a target arrangement in a deposition apparatus is described. The method may include inserting a fixation means in a recess, particularly a bore, which is provided in the target material to be deposited.

Embodiments are also directed at apparatuses for carrying out the disclosed methods and include apparatus parts for performing each described method step. These method steps may be performed by way of hardware components, a computer programmed by appropriate software, by any combination of the two or in any other manner. Furthermore, embodiments according to the invention are also directed at methods by which the described apparatus operates. It includes method steps for carrying out every function of the apparatus.

### BRIEF DESCRIPTION OF THE DRAWINGS

So that the manner in which the above recited features of the present invention can be understood in detail, a more particular description of the invention, briefly summarized above, may be had by reference to embodiments. The accompanying drawings relate to embodiments of the invention and are described in the following:

FIG. 1 shows a schematic view of a deposition apparatus suitable for a deposition process according to embodiments described herein;

FIG. 2 shows a schematic cross sectional view of a target arrangement according to embodiments described herein; and,

FIG. 3 shows a flow chart of a method of mounting a target arrangement in a deposition apparatus according to embodiments described herein.

### DETAILED DESCRIPTION OF EMBODIMENTS

Reference will now be made in detail to the various embodiments of the invention, one or more examples of which are illustrated in the figures. Within the following description of the drawings, the same reference numbers refer to same components. Generally, only the differences with respect to individual embodiments are described. Each example is provided by way of explanation of the invention and is not meant as a limitation of the invention. Further, features illustrated or described as part of one embodiment can be used on or in conjunction with other embodiments to yield yet a further embodiment. It is intended that the description includes such modifications and variations.

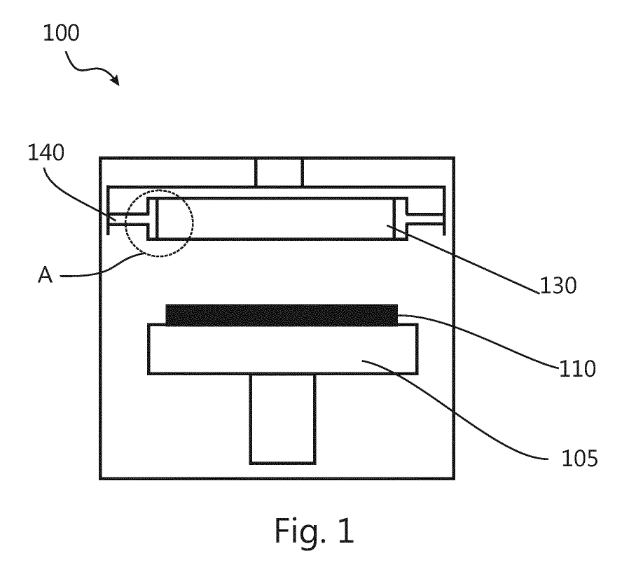

FIG. 1 shows a deposition chamber suitable for a sputter deposition process according to embodiments described herein. Typically, chamber 100 includes a substrate support 105, which is adapted for carrying a substrate 110. Further, chamber 100 includes a connecting device 140 for receiving and holding a target arrangement 130. The target arrangement provides the material to be deposited on substrate 110. According to some embodiments, the target arrangement 130 and the connecting device 140 for receiving and holding are adapted to rotate the target arrangement 130. Typically, the connecting device 140 may be able to connect the target arrangement 130 to a rotating shaft.

As used herein, the term “target arrangement” should be understood as an assembly which is adapted and suitable for providing deposition material in a deposition process, such as a sputter deposition process. The target arrangement may have a substantially cylindrical shape having a cylindrical surface and two face surfaces.

The term “substantially” in this context means that there may be a certain deviation from the characteristic denoted with “substantially.” For instance, the term “substantially cylindrical” refers to a shape which may have certain deviations from the exact cylindrical shape, such as a deviation of about 1 to 10% of the general extension in one direction. Also, the term “substantially cylindrical” may stand for a tube-like shape. According to some embodiments, “substantially cylindrical” includes that at least 80% or 90% of the element has a cylindrical shape.

When the target includes mild deposition materials such as high purity Al or Cu (for instance, Al or Cu having a purity of about 99.99% or 99.999%), it is known to weld components made of more rigid material on the target ends to allow proper connection of the target e.g. to the cathode drive. It is to be understood that the materials Al and Cu are mere examples for materials having a hardness not allowing to directly connect a rotation shaft of the deposition chamber to the target by conventional methods due to their material characteristic. For instance, for materials having a hardness in the range of about 40 HB to about 150 HB, it is known to support the connection of the target to a rotation shaft by an additional piece of material different from the target material. These additional parts and the additional process step of welding increase the costs for each target.

Typically, the target arrangement according to embodiments described herein may be adapted to be mounted in a deposition chamber and may include respective connection arrangements. According to some embodiments, the target arrangement includes a target part made from material to be deposited, which includes the connecting arrangement of the target arrangement. For instance, the connecting arrangement may be formed as a recess in a face surface of the cylindrically shaped target part. Typically, the connecting arrangement within the target part made from material to be deposited may be adapted to connect the target arrangement to the deposition apparatus, in which the target arrangement should be used. According to further embodiments, the connecting arrangement in the target part made from material to be deposited may be adapted to connect the target arrangement to a rotating shaft for rotating the target arrangement along its longitudinal axis.

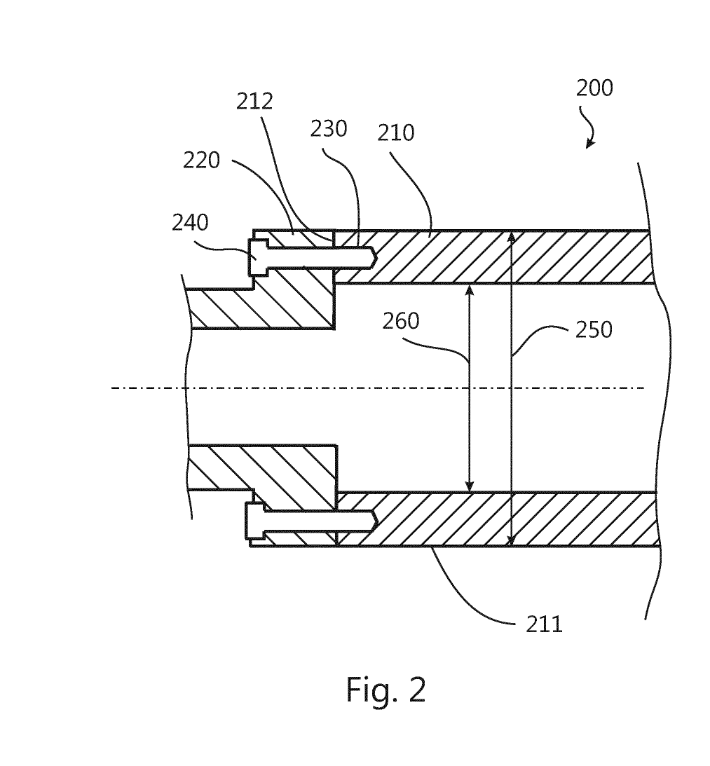

FIG. 2 shows the section A shown in FIG. 1 by a circle in dashed lines. According to some embodiments, a target arrangement 200 includes a target part 210 made of the material to be deposited. Typically, the target part 210 has substantially the shape of a hollow cylinder having an inner diameter 260 and an outer diameter 250. Further, the target part 210 provides a cylindrical surface 211 and two face surfaces, of which only one face surface 212 is shown in FIG. 2.

According to some embodiments, the target part may be a one-piece target part being made from the material to be deposited without any backing element, such as a backing tube or the like. For instance, in the case, where the material to be deposited is Al or Cu, the target part may be made from Al or Cu. Typically, the material of the target part may have a Mohs hardness in the range from about 2.5 to about 3.5. According to some embodiments, the difference between the outer diameter 250 and the inner diameter 260 is about 15 mm or greater, such as 30 mm, 40 mm or 60 mm. The inner diameter 260 may range from about 100 mm to about 135 mm and the outer diameter 250 of the target part 210 ranges from about 140 mm to about 175 mm.

When using targets with greater outer diameter so that the wall thickness of the cylindrically shaped target part is high enough (for instance, high enough to accommodate a recess for connecting the target arrangement), an additional welding of more rigid material may be avoided. Therefore, the target arrangement according to embodiments described herein allows for connecting the target arrangement directly, which may result in a cost reduction for manufacturing and recycling the target arrangement.

The target part 210 includes a recess 230 as a connecting arrangement. According to some embodiments, the recess 230 is formed in the material to be deposited. The recess 230 may be formed as a bore and may include a thread or the like for securing a counterpart in the recess 230. For instance, a connecting element 240 may be used for connecting the target arrangement to a deposition apparatus or a rotation shaft 220 of the deposition apparatus, in which the target assembly is to be used. Typically, the connecting element 240 may have a protrusion fitting in the recess of the target arrangement. In the example shown in FIG. 2, the protrusion of connecting element 240 is provided by a screw.

According to some embodiments, the recess of the target arrangement may have an insert for ensuring a proper connection of the connecting device and the target arrangement. For instance, the insert may be made from a material having a greater hardness than the material to be deposited. Typically, the insert may provide a thread. According to some embodiments, the material of the target part, in which the recess is formed, may typically have a hardness between about 40 HB to about 200 HB, more typically between about 70 HB and 170 HB, and even more typically between about 100 HB and about 150 HB. Also, further materials such as sintering alloys of aluminum may be used.

According to some embodiments, the target arrangement as described herein may be used as a rotatable target arrangement during static deposition. That means that the substrate may be held in a fix position during the deposition process, whereas the target arrangement may rotate around its longitudinal axis. Typically, the target arrangement shown herein may be used for coating large area substrates. According to other embodiments, the rotatable targets can be used for non-static deposition, wherein the substrate is transported by the one or more targets during deposition.

According to some embodiments, large area substrates may have a size of at least 0.174 m². Typically the size can be about 1.4 m² to about 8 m², more typically about 2 m² to about 9 m² or even up to 12 m². Typically, the substrates, for which the structures, apparatuses, such as cathode assemblies, and methods according to embodiments described herein are provided, are large area substrates as described herein. For instance, a large area substrate can be GEN 5, which corresponds to about 1.4 m² substrates (1.1 m×1.3 m), GEN 7.5, which corresponds to about 4.29 m² substrates (1.95 m×2.2 m), GEN 8.5, which corresponds to about 5.7 m² substrates (2.2 m×2.5 m), or even GEN 10, which corresponds to about 8.7 m² substrates (2.85 m×3.05 m). Even larger generations such as GEN 11 and GEN 12 and corresponding substrate areas can similarly be implemented.

Typically, a substrate as referred to herein may be made from any material suitable for material deposition. For instance, the substrate may be made from a material selected from the group consisting of glass (for instance soda-lime glass, borosilicate glass etc.), metal, polymer, ceramic, compound materials, carbon fiber materials or any other material or combination of materials which can be coated by a deposition process.

According to some embodiments, the deposition material may be chosen according to the deposition process and the later application of the coated substrate. For instance, the deposition material of the target may be a material selected from the group consisting of: a metal, such as aluminum, molybdenum, titanium, copper, or the like, silicon, indium tin oxide, and other transparent oxides. Typically, the target material may be an oxide ceramic, more typically, the material may be a ceramic selected from the group consisting of an indium containing ceramic, a tin containing ceramic, a zinc containing ceramic and combinations thereof. For instance, the deposition material may be IGZO.

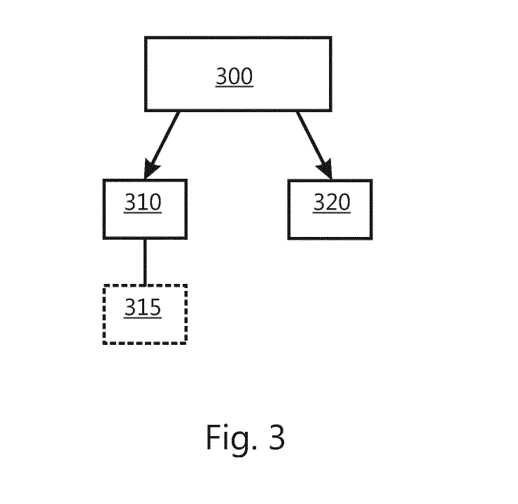

According to some embodiments, a method mounting a target arrangement in a deposition apparatus is provided. FIG. 3 shows a flow chart of a method according to embodiments described herein. Typically, the method 300 of mounting a target arrangement includes at block 310 inserting a fixation means in a recess. According to some embodiments, the recess may be a recess as described above with respect to FIG. 2. In particular, the recess may be a bore, which is indicated by block 315 in dashed lines. Further, the method of mounting a target arrangement according to embodiments described herein includes block 320 indicating that the fixation means is inserted in the target material to be deposited. For instance, a target part being made from the material to be deposited may be provided with a recess for accommodating the fixation means. Typically, the fixation means may be a connecting device, a bolt, a screw or the like, as exemplarily described with respect to FIG. 2.

According to some embodiments, inserting a fixation means includes screwing a screw in a thread provided in the recess of the target arrangement, such as a bore. According to some embodiments, inserting a fixation means includes screwing a screw in a thread provided in an insert provided within the bore.

While the foregoing is directed to embodiments of the invention, other and further embodiments of the invention may be devised without departing from the basic scope thereof, and the scope thereof is determined by the claims that follow.

1. A target arrangement for providing material to be deposited on a substrate, comprising:
a target part made of the material to be deposited, having substantially the shape of a hollow cylinder having an inner diameter and an outer diameter, wherein the hollow cylinder comprises a cylindrical surface and two face surfaces; and
a connection arrangement comprising a recess within at least one of the face surfaces of the target part, wherein the target arrangement is rotatable.

2. The target arrangement according to claim 1, wherein the recess is a bore.

3. The target arrangement according to claim 1, wherein the target part is a one-piece target part.

4. The target arrangement according to claim 1, wherein the material to be deposited is Al or Cu.

5. The target arrangement according to claim 1, wherein the difference between the inner diameter and the outer diameter in radial direction is about 30 mm or greater.

6. The target arrangement according to claim 1, wherein the material of the target part provides a Mohs hardness in the range from about 2.5 to about 3.5.

7. The target arrangement according to claim 1, wherein the connection arrangement further comprises an insert provided within the recess.

8. The target arrangement according to claim 2, wherein the bore or the insert comprises a thread configured for connecting the target arrangement with a screw.

9. A sputter deposition apparatus, comprising:
a target arrangement for providing material to be deposited on a substrate, comprising:
a target part made of the material to be deposited, having substantially the shape of a hollow cylinder having an inner diameter and an outer diameter, wherein the hollow cylinder comprises a cylindrical surface and two face surfaces; and
a connection arrangement comprising a recess within at least one of the face surfaces of the target part,
wherein the target arrangement is rotatable.

10. Method of mounting a target arrangement in a deposition apparatus, comprising:
inserting a fixation means in a recess, particularly a bore, which is provided in the target material to be deposited.

11. Method according to claim 9, wherein the inserting comprises screwing a screw in a thread provided in the bore or an insert provided within the bore.

12. The target arrangement according to claim 2, wherein the target part is a one-piece target part.

13. The target arrangement according to claim 1, wherein the connecting arrangement is adapted to connect the target arrangement to a rotating shaft for rotating the target arrangement along its longitudinal axis.

14. The target arrangement according to claim 3, wherein the connecting arrangement is adapted to connect the target arrangement to a rotating shaft for rotating the target arrangement along its longitudinal axis.

15. The target arrangement according to claim 3, wherein the material to be deposited is Al or Cu.

16. The target arrangement according to claim 3, wherein the difference between the inner diameter and the outer diameter in radial direction is about 30 mm or greater.

17. The target arrangement according to claim 3, wherein the material of the target part provides a Mohs hardness in the range from about 2.5 to about 3.5.

18. The target arrangement according to claim 13, wherein the insert comprises a thread configured for connecting the target arrangement with a screw.

19. The sputter deposition apparatus according to claim 16, wherein the target part is a one-piece target part.

20. The sputter deposition apparatus according to claim 16, wherein the connecting arrangement is adapted to connect the target arrangement to a rotating shaft for rotating the target arrangement along its longitudinal axis.
